(19) United States
(12) Patent Application Publication
(10) Pub. No.: US 2017/0186611 A1
(43) Pub. Date: Jun. 29, 2017

(54) POLYCRYSTALLINE SILICON THIN FILM AND METHOD THEREOF, OPTICAL FILM, AND THIN FILM TRANSISTOR

(71) Applicant: BOE TECHNOLOGY GROUP CO., LTD, Beijing (CN)

(72) Inventors: DONG LI, Beijing (CN); XIAOYONG LU, Beijing (CN); SHUAI ZHANG, Beijing (CN); ZHENG LIU, Beijing (CN); CHUNPING LONG, Beijing (CN)

(21) Appl. No.: 15/305,588

(22) PCT Filed: Apr. 6, 2016
(86) PCT No.: PCT/CN2016/078561

§ 371 Date: Oct. 20, 2016

(30) Foreign Application Priority Data
Aug. 20, 2015 (CN) 2015-10516303.3

(51) Int. Cl. H01L 21/02; G02B 27/09; H01L 29/786

(52) U.S. Cl. CPC H01L 21/02678; H01L 21/02532; H01L 21/02592; H01L 29/78672; G02B 27/0988

(57) ABSTRACT

In accordance with various embodiments of the disclosed subject matter, a method for forming polycrystalline silicon thin film, a related optical film, a related polycrystalline silicon thin film, and a related thin film transistor are provided. In some embodiments, the method comprises: providing an amorphous silicon thin film; and performing a laser annealing process to convert the amorphous silicon thin film into a polycrystalline silicon thin film through generating a laser irradiation having a spatially periodic intensity distribution to irradiate the amorphous silicon thin film; wherein the spatially periodic intensity distribution comprises: a first laser intensity to form a plurality of crystal nuclei regions arranged in an array, and a second laser intensity to form a plurality of epitaxial growth regions, the second laser intensity being greater than the first laser intensity.

### CROSS-REFERENCES TO RELATED APPLICATIONS

This PCT patent application claims priority of Chinese Patent Application No. 201510516303.3 filed on Aug. 20, 2015, the entire content of which is incorporated by reference herein.

### TECHNICAL FIELD

The disclosed subject matter generally relates to semiconductor technologies and, more particularly, relates to a method for forming polycrystalline silicon thin film, a related optical film, a related polycrystalline silicon thin film, and a related thin film transistor.

### BACKGROUND

Polycrystalline silicon, also called polysilicon, is a kind of form of monatomic silicon. Polycrystalline silicon can be formed by solidifying the melted amorphous silicon in a cold condition. At present, polycrystalline silicon is widely used in forming polycrystalline silicon thin films.

In an existing method of forming a polycrystalline silicon thin film, an amorphous silicon thin film can be firstly formed on a substrate, and then the amorphous silicon thin film can be annealed by laser irradiation. The amorphous silicon thin film can be melted by the laser, and then can be cooled and gradually form crystal grains by using impurities in the amorphous silicon thin film as crystal nuclei. Finally, the amorphous silicon thin film can be transformed into a polycrystalline silicon thin film.

However, the existing method has at least the following disadvantages. Since impurities in the amorphous silicon thin film is unevenly distributed, the crystal nuclei in the polycrystalline silicon thin film formed by the existing method is also unevenly distributed. Therefore the interfaces between neighboring crystal grains (crystal grain boundaries) are irregular. The irregularly arranged crystal grain boundaries can result in low electrical properties of an electronic devices made of the polycrystalline silicon thin film, such as a thin film transistor.

Accordingly, it is desirable to provide a method for forming polycrystalline silicon thin film, a related optical film, a related polycrystalline silicon thin film, and a related thin film transistor to at least partially alleviate one or more problems set forth above and to solve other problems in the art.

### BRIEF SUMMARY

In accordance with some embodiments of the disclosed subject matter, a method for forming polycrystalline silicon thin film, a related optical film, a related polycrystalline silicon thin film, and a related thin film transistor are provided.

An aspect of the present disclosure provides a method for forming a polycrystalline silicon thin film, comprising: providing an amorphous silicon thin film; and performing a laser annealing process to convert the amorphous silicon thin film into a polycrystalline silicon thin film through generating a laser irradiation having a spatially periodic intensity distribution to irradiate the amorphous silicon thin film; wherein the spatially periodic intensity distribution comprises: a first laser intensity to form a plurality of crystal nuclei regions arranged in an array, and a second laser intensity to form a plurality of epitaxial growth regions, the second laser intensity being greater than the first laser intensity.

In some embodiments, the laser annealing process further comprising: a cooling process to form multiple crystal grains that grow from the crystal nuclei regions.

In some embodiments, the first laser intensity is less than a critical intensity value that is a minimum intensity of a laser irradiation to completely melt the amorphous silicon thin film.

In some embodiments, the method of claim further comprises: using an optical film to control the spatially periodic intensity distribution of the laser irradiation, wherein: the optical film comprises a plurality of optical plates that are arranged in an array, and a laser beam going through each optical plate has a central symmetrical intensity distribution.

In some embodiments, the plurality of optical plates are arranged as a matrix; and the spatially periodic intensity distribution of the laser irradiation is capable of converting an amorphous silicon thin film into a polycrystalline silicon thin film comprising rectangular crystal grains.

In some embodiments, the plurality of optical plates are arranged as a parallelogram array; and the spatially periodic intensity distribution of the laser irradiation is capable of converting an amorphous silicon thin film into a polycrystalline silicon thin film comprising hexagonal crystal grains.

In some embodiments, the optical film comprises a plurality of weak light regions; and a laser beam going through each weak light region has an intensity that is less than the critical intensity value.

In some embodiments, the method further comprises: providing a base substrate, wherein the amorphous silicon thin film is formed on the base substrate; and forming a barrier layer between the base substrate and the amorphous silicon thin film.

In some embodiments, the crystal nuclei are located in one side of the polycrystalline silicon thin film that is close to the base substrate.

Another aspect of the present disclosure provides an optical film for forming a polycrystalline silicon thin film, comprising: a plurality of optical plates arranged in an array for generating a spatially periodic intensity distribution of a laser irradiation through the optical film; and a plurality of weak light regions for forming a plurality of crystal nuclei regions arranged in an array.

In some embodiments, each weak light region is used for controlling an intensity of laser going through the region to incompletely melt a corresponding region of an amorphous silicon thin film.

In some embodiments, the plurality of optical plates are arranged as a matrix; and the spatially periodic intensity distribution of the laser irradiation is capable of converting an amorphous silicon thin film into a polycrystalline silicon thin film comprising rectangular crystal grains.

In some embodiments, the plurality of optical plates are arranged as a parallelogram array; and the spatially periodic intensity distribution of the laser irradiation is capable of converting an amorphous silicon thin film into a polycrystalline silicon thin film comprising hexagonal crystal grains.

In some embodiments, each optical plate is a zone plate.

In some embodiments, each optical plate is a Fresnel zone plate.

In some embodiments, each optical plate is a convex lens.

In some embodiments, each optical plate has a quadrilateral shape.

In some embodiments, each optical plate is configured for quadrilaterally converging an incident light.

Another aspect of the present disclosure provides a polycrystalline silicon thin film, comprising a polycrystalline silicon thin film formed by the disclosed method.

Another aspect of the present disclosure provides a thin film transistor, comprising a disclosed polycrystalline silicon thin film.

Other aspects of the present disclosure can be understood by those skilled in the art in light of the description, the claims, and the drawings of the present disclosure.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements. It should be noted that the following drawings are merely examples for illustrative purposes according to various disclosed embodiments and are not intended to limit the scope of the present disclosure.

FIG. 1 is a flowchart of an exemplary method for forming a polycrystalline silicon thin film in accordance with some embodiments of the disclosed subject matter;

FIG. 2-1 is a flowchart of another exemplary method for forming a polycrystalline silicon thin film in accordance with some other embodiments of the disclosed subject matter;

FIG. 2-2 is a schematic diagram of a laser annealing process in accordance with some embodiments of the disclosed subject matter;

FIG. 3-1 is a schematic structural diagram of an exemplary optical film in accordance with some embodiments of the disclosed subject matter;

FIG. 3-2 is a schematic diagram of crystal nuclei on an amorphous silicon thin film in accordance with some embodiments of the disclosed subject matter;

FIG. 3-3 is a schematic diagram of an exemplary polycrystalline silicon thin film in accordance with some embodiments of the disclosed subject matter;

FIG. 3-4 is a schematic structural diagram of an exemplary optical filth in accordance with some other embodiments of the disclosed subject matter;

FIG. 3-5 is a schematic diagram of crystal nuclei on an amorphous silicon thin film in accordance with some other embodiments of the disclosed subject matter;

FIG. 3-6 is a schematic diagram of an exemplary polycrystalline silicon thin film in accordance with some other embodiments of the disclosed subject matter;

FIG. 3-7 is a schematic diagram of a semiconductor layer of a thin film transistor in accordance with some other embodiments of the disclosed subject matter;

FIG. 3-8 is a schematic structural diagram of an exemplary optical film in accordance with some other embodiments of the disclosed subject matter; and

FIG. 3-9 is a schematic structural diagram of an exemplary optical film in accordance with some other embodiments of the disclosed subject matter.

### DETAILED DESCRIPTION

For those skilled in the art to better understand the technical solution of the disclosed subject matter, reference will now be made in detail to exemplary embodiments of the disclosed subject matter, which are illustrated in the accompanying drawings. Wherever possible, the same reference numbers will be used throughout the drawings to refer to the same or like parts.

In accordance with various embodiments, the disclosed subject matter provides a method for forming a polycrystalline silicon thin film, a related optical film, a related polycrystalline silicon thin film, and a related thin film transistor.

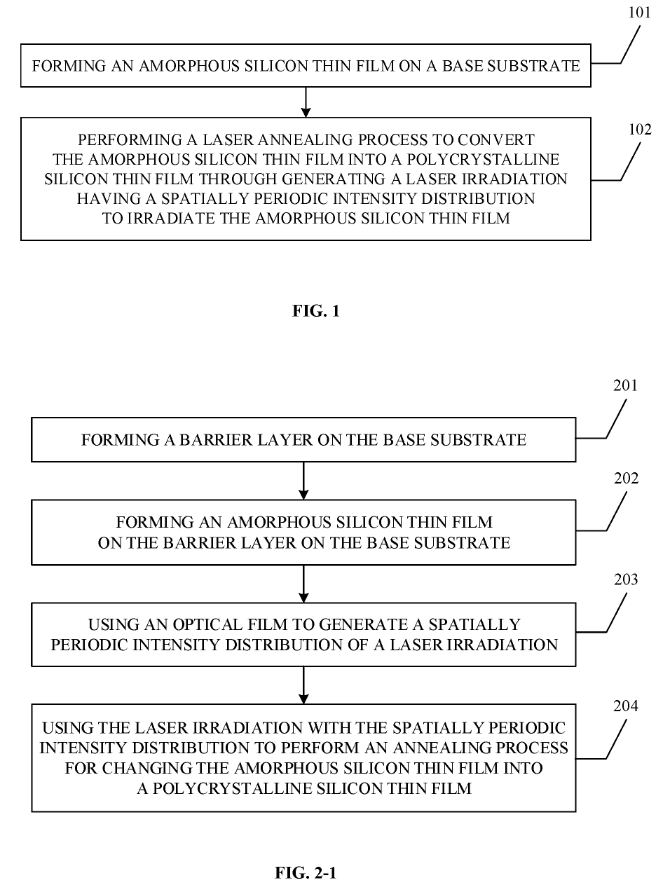

Referring to FIG. 1, a flowchart of an exemplary method for forming a polycrystalline silicon thin film is shown in accordance with some embodiments of the disclosed subject matter. As illustrated, the method may include the following exemplar steps.

Step 101: forming an amorphous silicon thin film on a base substrate.

Step 102: performing a laser annealing process to convert the amorphous silicon thin film into a polycrystalline silicon thin film through generating a laser irradiation having a spatially periodic intensity distribution to irradiate the amorphous silicon thin film. During the laser annealing process, an intensity distribution of the laser irradiation on the amorphous silicon thin film can be controlled and formed a spatially periodic pattern, so that different portions of the amorphous silicon thin film can receive laser irradiation with different intensities.

For example, an irradiation region on the amorphous silicon thin film can include multiple sub-regions that are arranged in an array. Corresponding to each sub-region, a portion of the amorphous silicon thin film can be irradiated by a laser with a controlled intensity that is less than a critical intensity value, The portions of the amorphous silicon corresponding to each sub-region may be incompletely melted under the laser irradiation with a. controlled intensity that is less than the critical intensity value, and can form multiple crystal nuclei that are also arranged in an array.

Therefore, the portions of the amorphous silicon corresponding to each sub-region are defined as crystal nuclei regions. And the portion of the amorphous silicon that do not correspond to each sub-region may be completely melted under the laser irradiation, and are defined as epitaxial growth regions.

Accordingly, a method for forming polycrystalline silicon thin film is provided. In some embodiments, the method comprises: providing an amorphous silicon thin film; and performing a laser annealing process to convert the amorphous silicon thin film into a polycrystalline silicon thin film through generating a laser irradiation having a spatially periodic intensity distribution to irradiate the amorphous silicon thin film; wherein the spatially periodic intensity distribution comprises: a first laser intensity to form a plurality of crystal nuclei regions arranged in an array, and a second laser intensity to form a plurality of epitaxial growth regions, the second laser intensity being greater than the first laser intensity.

The disclosed method can solve the problem of low electrical properties of an electronic devices made of a polycrystalline silicon thin film with irregularly arranged crystal grain boundaries. A polycrystalline silicon thin film formed by the disclosed method can have regularly arranged crystal grain boundaries. An electronic devices made by the polycrystalline silicon thin film can have improved electrical properties.

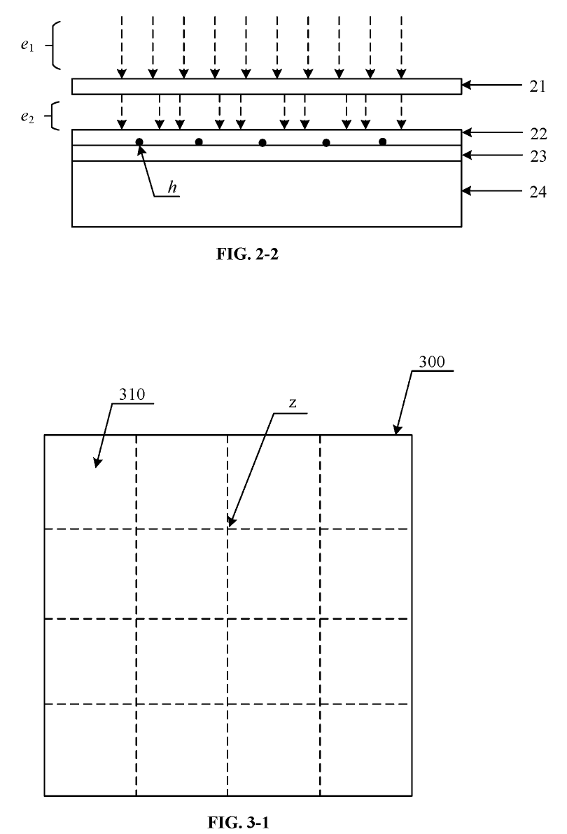

Referring to FIG. 2-1, a flowchart of an exemplary method for forming a polycrystalline silicon thin film is shown in accordance with some other embodiments of the disclosed subject matter. As illustrated, the method may include the following exemplary steps.

Step 201: forming a barrier layer on the base substrate.

The barrier layer is used for preventing the amorphous silicon thin film from being in contact with the base substrate, The barrier layer may be made by any suitable material that does not react with the amorphous silicon thin film in a molten state.

Since the amorphous silicon thin film in the molten state may react with the base substrate in subsequent steps, the reaction may produce damages to the base substrate, and may produce many impurities in the polycrystalline silicon thin film obtained later. The barrier layer can play a protective role of the amorphous silicon thin film and the base substrate. In addition, the barrier layer can also be used to maintain the temperature of the amorphous silicon thin film in the molten state in order to avoid a too fast cooling rate of the amorphous silicon thin film in the molten state. A too fast cooling rate of the amorphous silicon thin film in the molten state can cause a problem that the generated crystal grains are too small, and thereby result in a negative impact of the electrical properties of the electrical device made by the amorphous silicon thin film.

Step 202: forming an amorphous silicon thin film on the barrier layer on the base substrate.

In some embodiments, the amorphous silicon thin film can be formed by a plasma enhanced chemical vapor deposition (PECVD) method over the base substrate.

Step 203, using an optical film to generate a spatially periodic intensity distribution of a laser irradiation.

After forming the amorphous silicon thin film on the barrier layer on the base substrate, a laser annealing process can be performed on the amorphous silicon thin film. During the laser annealing process, a laser beam emitted from a laser generator can go through an optical film to provide a laser irradiation with a spatially periodic intensity distribution.

In some embodiments, the optical film can include multiple optical plates arranged in an array. A laser beam going through each optical plate can have a central symmetrical intensity distribution that decreases along a direction outwardly from the center of the optical plate.

In some embodiments, an optical plate can be a convex lens, or a zone plate such as a Fresnel zone plate. An optical plate can be a round optical plate for providing roundly condensed light, or be a quadrilateral optical plate for providing quadrilaterally condensed light.

A weak light region can be defined as a region on the optical film that the intensity of laser going through the region is less than the critical intensity value. Since multiple optical plates are arranged in an array in the optical film, multiple weak light regions may be staggered with the multiple optical plates, and are also arranged in an array in the optical film.

In some embodiments, a laser going through the weak light region can incompletely melt the amorphous silicon thin film.

It should be noted that, the amorphous silicon can be incompletely melted under a laser irradiation with a spatially periodic intensity that is less than the critical intensity value, while the amorphous silicon can be completely melted under a laser irradiation with a controlled intensity that is greater than the critical intensity value.

It also should be noted that a laser irradiated region of the optical film at an instance may be any suitably shaped region, such as a round-shaped region, a rectangle-shaped region, a bar-shaped region, a sector-shaped region, etc. For example, when the laser irradiated region on the optical film is a bar-shaped region, such bar-shaped region may be used to scan the optical film by changing the emission direction of the laser or any other suitable mechanism. In addition, the laser intensities of the laser irradiated regions, such as the bar-shaped regions, at different locations of the optical film may be the same or different, as long as the laser intensities going through the weak light regions of the optical film are less than the critical intensity value, and the laser intensities going through all other regions of the optical film are greater than the critical intensity value.

Step 204, using the laser irradiation with the spatially periodic intensity distribution to perform an annealing process for changing the amorphous silicon thin film into a polycrystalline silicon thin film.

Referring to FIG. 2-2, a schematic diagram of a laser annealing process is shown in accordance with some embodiments of the disclosed subject matter.

As illustrated, barrier layer 23 is formed on the base substrate 24, an amorphous silicon thin film 22 is formed on the barrier layer 23. A laser beam e1 can go through the optical film 21 to form a laser irradiation e2 with a controlled intensity distribution having various laser intensities. The laser irradiation e2 with a spatially periodic intensity distribution can irradiate the amorphous silicon thin film 22 to form multiple crystal nuclei h corresponding to the multiple weak light regions on the optical film 21.

Laser annealing process is an important technique to adjust the microstructure of a material. Laser annealing process can not only heat and cool a material rapidly, but also avoid a high temperature treatment that may cause damage to the base substrate, and avoid a prolonged high temperature heating process that may cause impurities diffusion between the base substrate and the thin film.

In some embodiments of the disclosed subject matter, an excimer laser can be used as a laser source during the laser annealing process.

In one embodiment, a laser annealing process can include the following exemplary steps. A laser irradiation on the surface of an amorphous silicon thin film can increase the temperature of the amorphous silicon thin film. Some portions of the amorphous silicon thin film corresponding to the multiple weak light regions of the optical film are irradiated by a laser with a controlled intensity that is less than a critical intensity value, the portions of amorphous silicon can be incompletely melted to form multiple nuclei. Some other portions of the amorphous silicon thin film are irradiated by a laser with a controlled intensity greater than the critical intensity value, those other portions of the amorphous silicon can be completely melted. In a cooling stage after the laser irradiation is stopped, the molten amorphous silicon thin film can gradually form multiple crystal grains that grow outwardly from the crystal nuclei as centers. The crystal grains usually have consistent outgrowth rate, and therefore the regularly arranged crystal nuclei can ensure that the crystal grain boundaries are also regularly arranged. When the molten amorphous silicon thin film are completely converted into regularly arranged crystal grains, the amorphous silicon thin film is converted into a polysilicon thin film.

It should be noted that, in the disclosed method for foaming a polysilicon thin film, a barrier layer is provided between the amorphous silicon thin film and the base substrate for protecting the amorphous silicon thin film and the base substrate, and also for avoiding a too fast cooling rate of the molten amorphous silicon thin film which may cause a problem that the generated crystal grains are too small.

Accordingly, a method for forming polycrystalline silicon thin film is provided. In some embodiments, the method comprises: providing an amorphous silicon thin film comprising a plurality of first sub-regions arranged in an array and at least one second sub-region; and performing a laser annealing process to convert the amorphous silicon thin film into a polycrystalline silicon thin film, comprising: laser-irradiating the amorphous silicon thin film using a first laser intensity to incompletely melt the amorphous silicon thin film in the plurality of first sub-regions to be used as crystal nuclei, and using a second laser intensity greater than the first laser intensity to melt the amorphous silicon thin film in the at least one second sub-region.

The disclosed method can solve the problem of low electrical properties of an electronic devices made of a polycrystalline silicon thin film with irregularly arranged crystal grain boundaries. A polycrystalline silicon thin film formed by the disclosed method can have regularly arranged crystal grain boundaries. An electronic devices made by the polycrystalline silicon thin film can have improved electrical properties.

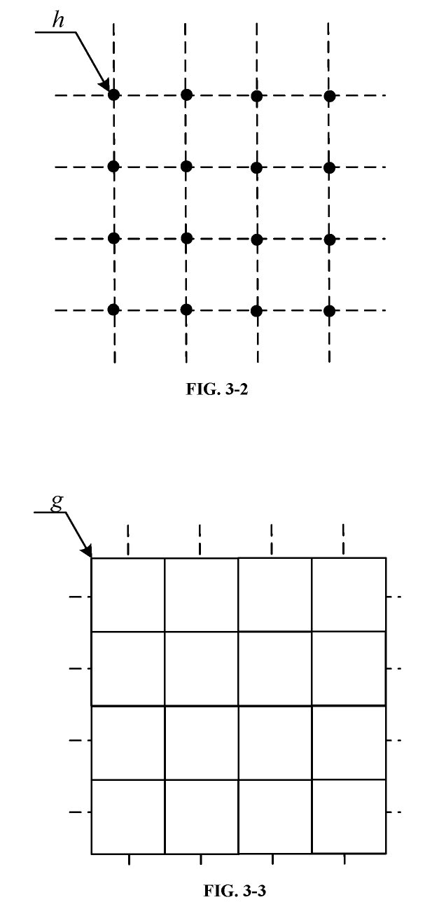

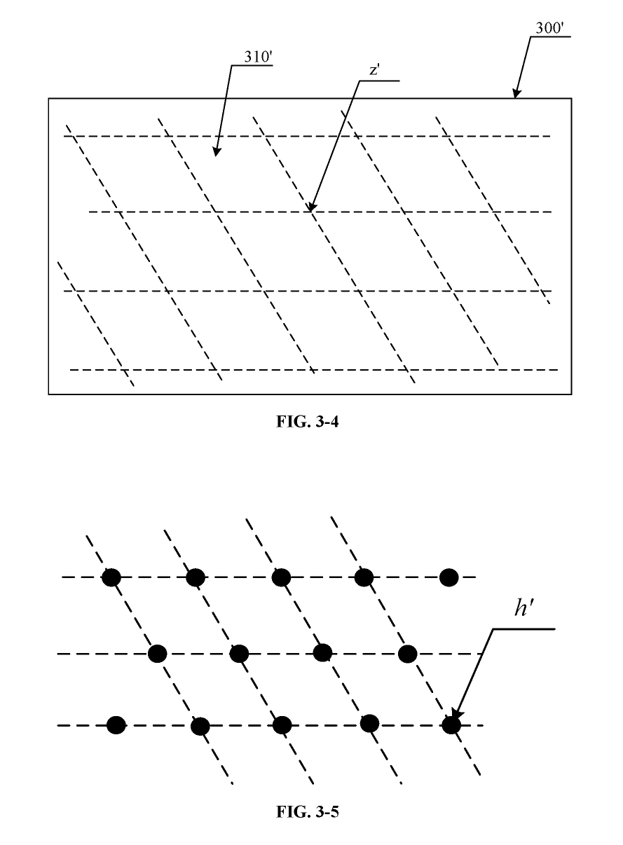

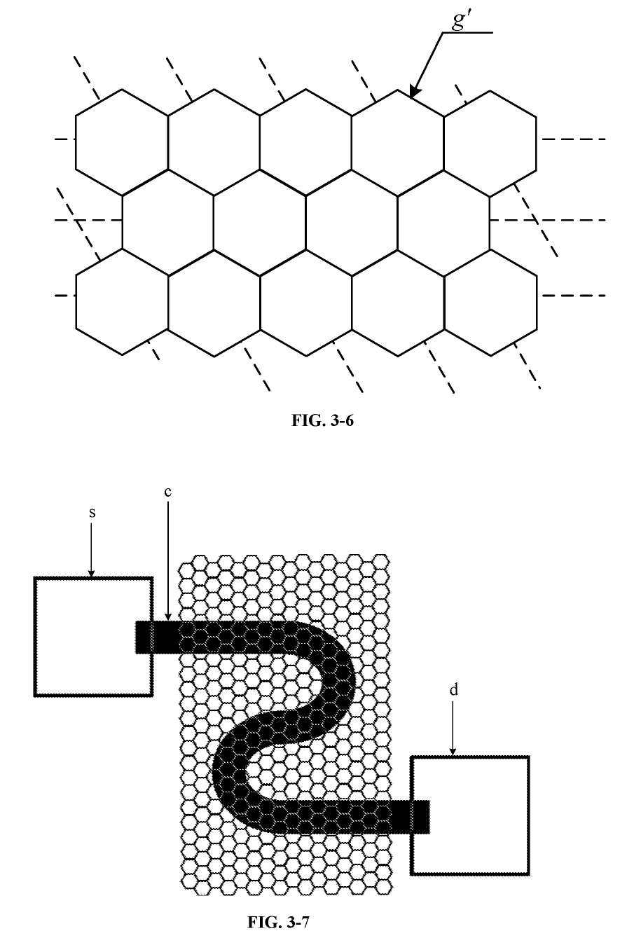

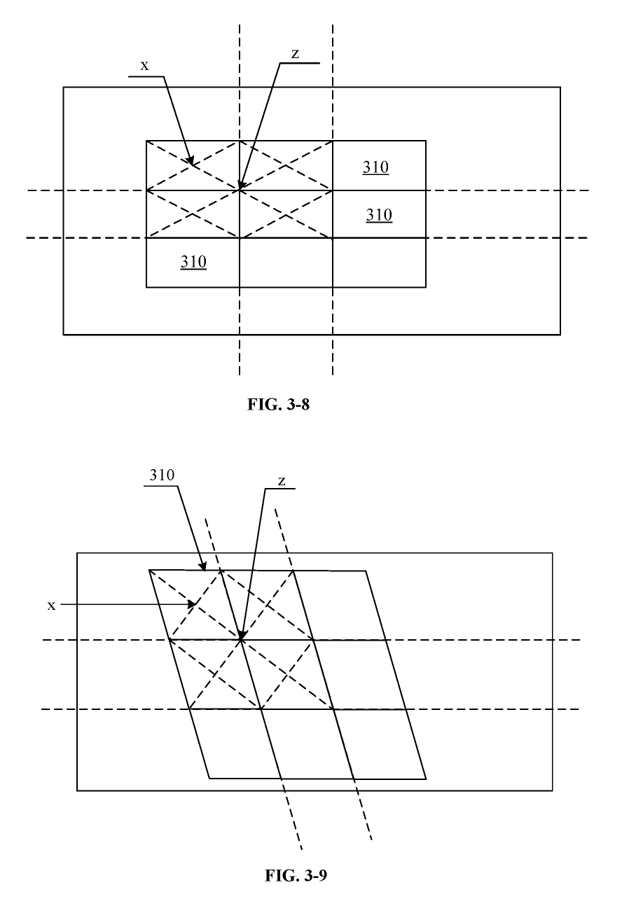

Referring to FIG. 3-1, a schematic structural diagram of an exemplary optical film 300 is shown in accordance with some embodiments of the disclosed subject matter. Note that although the optical plates are shown having a quadrate shape in FIG. 3-1, the optical plates disclosed herein may include any suitably-shaped optical plates without limitation.

As illustrated, multiple optical plates 310 are arranged in an array in the optical film 300. The multiple optical plates 310 are used for controlling the intensity distribution of the laser irradiation going through the optical film 300 to provide different laser intensities.

In some embodiments, the multiple optical plates 310 are arranged as a matrix, and each optical plate 310 has a quadrate shape, or a round shape. Each optical plate 310 can be a convex lens, or a zone plate such as a Fresnel zone plate. In one embodiment, each optical plate 310 has a quadrate shape that is formed by cutting a round convex lens, or a zone plate.

A laser beam going through each optical plate 310 can have a central, symmetrical intensity distribution that decreases along a direction outwardly from the center of each optical plate 310. That is, the intensity of the laser going through the center of each optical plate 310 is the strongest, and the intensity of the laser going through locations z is the weakest and less than the critical intensity value. The laser going through locations z with intensity less than the critical intensity value can incompletely melt the amorphous silicon, and the incompletely melted amorphous silicon corresponding to locations z can form multiple crystal nuclei. Therefore, the regions near locations z are weak light regions of the optical film 300.

In some embodiments, the multiple optical plates 310 are arranged throughout the optical film 300. Each location z is surrounded by four adjacent optical plates 310. Taking each location z as a center, multiple concave structures can be formed corresponding to multiple locations z. The multiple concave structures can ensure that the intensity of laser going through locations z near is less than the critical intensity value.

Referring to FIG. 3-2, a schematic diagram of crystal nuclei on an amorphous silicon thin film is shown in accordance with some embodiments of the disclosed subject matter.

As illustrated, crystal nuclei h arranged in a matrix can be formed on amorphous silicon thin film by using the optical film 300. When the molten amorphous silicon thin film is nucleating in the cooling process, crystal grains are growing outwardly from the multiple crystal nuclei h as centers. Since generally every crystal grains are growing in a same rate in all directions, the crystal grain boundaries between adjacent crystal grains are perpendicular bisectors of the lines between neighboring crystal nuclei h.

Referring to FIG. 3-3, a schematic diagram of an exemplary polycrystalline silicon thin film is shown in accordance with some embodiments of the disclosed subject matter.

After the amorphous silicon thin film converted into a polycrystalline silicon thin film using the optical film 300, the structure of the polycrystalline silicon thin film can be shown in FIG. 3-3. Each crystal grains g are rectangular.

Referring to FIG. 3-4, a schematic structural diagram of another exemplary optical film is shown in accordance with some other embodiments of the disclosed subject matter.

As illustrated, multiple optical plates 310′ are arranged in an array in the optical film 300′. The multiple optical plates 310′ are used for controlling the intensity distribution of the laser irradiation going through the optical film 300′.

In some embodiments, the multiple optical plates 310′ are arranged as a parallelogram array, and each optical plate 310′ has a parallelogram shape. In one embodiments, each optical plate 310′ has a parallelogram shape that is formed by cutting a round convex lens, or a zone plate.

A laser beam going through each optical plate 310′ can have a central symmetrical intensity distribution that decreases along a direction outwardly from the center of each optical plate 310′. That is, the intensity of the laser going through the center of each optical plate 310′ is the strongest, and the intensity of the laser going through locations z′ is the weakest and less than the critical intensity value. The laser going through locations z′ with intensity less than the critical intensity value can incompletely melt the amorphous silicon, and the incompletely melted amorphous silicon corresponding to locations z′ can be used as crystal nuclei. Therefore, the regions near locations z′ are weak light regions of the optical film 300′.

In some embodiments, the multiple optical plates 310′ are arranged throughout the optical film 300′. Each location z′ is surrounded by four adjacent optical plates 310′. Taking each location z′ as a center, multiple concave structures can be formed corresponding to multiple locations z′ on the optical film 310′. The multiple concave structures can ensure that the intensity of laser going through locations z′ or nearby region is less than the critical intensity value.

Referring to FIG. 3-5, a schematic diagram of crystal nuclei on an amorphous silicon thin film is shown in accordance with some other embodiments of the disclosed subject matter.

As illustrated, crystal nuclei h′ arranged in a parallelogram array can be formed on amorphous silicon thin film by using the optical film 300′. When the molten amorphous silicon thin film is nucleating in the cooling process, crystal grains are growing outwardly from the multiple crystal nuclei h′ as centers. Since generally every crystal grains are growing in a same rate in all directions, the crystal grain boundaries between adjacent crystal grains are perpendicular bisectors of the lines between neighboring crystal nuclei h′.

Referring to FIG. 3-6, a schematic diagram of an exemplary polycrystalline silicon thin film is shown in accordance with some other embodiments of the disclosed subject matter.

After the amorphous silicon thin film being converted into a polycrystalline silicon thin film using the optical film 300′, the structure of the polycrystalline silicon thin film can be shown in FIG. 3-6. Each crystal grains g′ are hexagonal.

As illustrated in connection with FIGS. 3-3 and 3-6, the sizes and shapes of the regularly arranged crystal grains can be determined by the sizes and shapes of the optical plate of the optical film. For example, the sizes and shapes of the optical plate of the optical film can control the positions of the generated multiple crystal nuclei. And the positions of the multiple crystal nuclei determine the sizes and shapes of the regularly arranged crystal grains.

Referring to FIG. 3-7, a schematic diagram of a semiconductor layer of a thin film transistor is shown in accordance with some other embodiments of the disclosed subject matter.

It should be noted that, hexagonal crystal grains have higher spatial symmetry compared to rectangular crystal grains. As illustrated, a semiconductor layer of a thin film transistor is formed by using a polycrystalline silicon thin film including multiple hexagonal crystal grains. If a channel region c between the source s and drain d is a curved channel shown in FIG. 3-7, the hexagonal crystal grains can improve the uniformity of the entire channel by increasing the number of crystal nuclei or the number of crystal grain boundaries. Thereby, the electrical properties of the semiconductor layer of the thin film transistor can be increased.

Referring to FIG. 3-8, a schematic structural diagram of an exemplary optical film is shown in accordance with some other embodiments of the disclosed subject matter.

As illustrated, in some embodiments, each optical plate 310 can have a quadrilateral shape, or in particular, a rectangular shape. In some embodiments, the multiple optical plates 310 are arranged throughout the entire optical film. A center x of each rectangle is an intersection of the rectangle diagonals. The intensity of the laser going through the center x of each optical plate 310 is the strongest, and the intensity distribution decreases along a direction outwardly from the center x of each optical plate 310.

A location z is the center of a larger rectangle formed by four adjacent rectangular optical plates 310. Taking each location z as a center, multiple concave structures can be formed corresponding to multiple locations z. The intensity of the laser going through locations z is the weakest and less than the critical intensity value. The laser going through locations z with intensity less than the critical intensity value can incompletely melt the amorphous silicon, and the incompletely melted amorphous silicon corresponding to locations z can be used as crystal nuclei. Therefore, the regions near locations z, e.g., centered by locations z, are weak light regions of the optical film. A polycrystalline silicon thin film formed by using the optical film shown in FIG. 3-8 can have a crystal structure similar to the one shown in FIG. 3-2.

Referring to FIG. 3-9, a schematic structural diagram of an exemplary optical film is shown in accordance with some other embodiments of the disclosed subject matter.

As illustrated, in some embodiments, each optical plate 310 can be a parallelogram. In some embodiments, the multiple optical plates 310 are arranged throughout the entire optical film. A center x of each parallelogram is an intersection of the parallelogram diagonals. The intensity of the laser going through the center x of each optical plate 310 is the strongest, and the intensity distribution decreases along a direction outwardly from the center x of each optical plate 310.

A location z is the center of a larger parallelogram formed by four adjacent parallelogram optical plates 310. Taking each location z as a center, multiple concave structures can be formed corresponding to multiple locations z. The intensity of the laser going through locations z is the weakest and less than the critical intensity value. The laser going through locations z with intensity less than the critical intensity value can incompletely melt the amorphous silicon, and the incompletely melted amorphous silicon corresponding to locations z can be used as crystal nuclei. Therefore, the regions near locations z, e.g., centered by locations z, are weak light regions of the optical film. A polycrystalline silicon thin film formed by using the optical film shown in FIG. 3-9 can have a crystal structure similar to the one shown in FIG. 3-5.

In some embodiments, the optical plate can be a convex lens, or a zone plate such as a Fresnel zone plate. Both the convex lens or zone plate can converge a laser beam to make a greater intensity of the laser. The parameters of the convex lens or zone plate can be adjusted for a desirable laser intensity.

It should be noted that, by using the disclosed optical film during the laser annealing process, although the formed polycrystalline silicon thin film includes multiple amorphous silicon crystal nuclei, the multiple amorphous silicon crystal nuclei are usually only located in one side of the polycrystalline silicon thin film that is close to the base substrate, because this side is farther from the optical film and being received weaker intensity of laser irradiation than the other side. When the polycrystalline silicon thin film is used as a semiconductor layer of a thin film transistor, a channel region is formed on one side of the polycrystalline silicon thin film that is generally away from the base substrate, and thus the amorphous silicon crystal nuclei do not affect the electrical properties of the polycrystalline silicon thin film.

It also should be noted that, the disclosed optical film includes multiple optical plates that are arranged in an array, and can be used to control an intensity distribution of a laser irradiation to form multiple crystal nuclei on an amorphous silicon thin film, and ultimately to form an polycrystalline silicon thin film including crystal grains with regularly arranged crystal grain boundaries. The crystal grains with regularly arranged crystal grain boundaries can improve the electrical properties of the polycrystalline silicon thin film, such as the carrier mobility and the threshold voltage uniformity throughout the polycrystalline silicon thin film.

Accordingly, a method for forming polycrystalline silicon thin film is provided. In some embodiments, the method comprises: providing an amorphous silicon thin film; and performing a laser annealing process to convert the amorphous silicon thin film into a polycrystalline silicon thin film through generating a laser irradiation having a spatially periodic intensity distribution to irradiate the amorphous silicon thin film; wherein the spatially periodic intensity distribution comprises: a first laser intensity to form a plurality of crystal nuclei regions arranged in an array, and a second laser intensity to form a plurality of epitaxial growth regions, the second laser intensity being greater than the first laser intensity.

It should be noted that, the laser irradiation having a spatially periodic intensity distribution can be generated using any suitable method, such as using a disclosed optical film described above in connection with FIGS. 3-1 and 3-4, or using an intensity adjustable laser device to performed a periodic scanning, etc.

The disclosed method can solve the problem of low electrical properties of an electronic devices made of a polycrystalline silicon thin film with irregularly arranged crystal grain boundaries. A polycrystalline silicon thin film formed by the disclosed method can have regularly arranged crystal grain boundaries. An electronic devices made by the polycrystalline silicon thin film can have improved electrical properties.

Another aspect of the disclosed subject matter provides a polycrystalline silicon thin film that are formed using any one of the methods described above in connection with FIGS. 1 and 2.

Another aspect of the disclosed subject matter provides a thin film transistor including any one of the polycrystalline silicon thin film described above in connection with FIGS. 3-3 and 3-6.

The provision of the examples described herein (as well as clauses phrased as “such as,” “e.g.,” “including,” and the like) should not be interpreted as limiting the claimed subject matter to the specific examples; rather, the examples are intended to illustrate only some of many possible aspects.

Accordingly, a method for forming polycrystalline silicon thin film, a related optical film, a related polycrystalline silicon thin film, and a related thin film transistor are provided.

Although the disclosed subject matter has been described and illustrated in the foregoing illustrative embodiments, it is understood that the present disclosure has been made only by way of example, and that numerous changes in the details of embodiment of the disclosed subject matter can be made without departing from the spirit and scope of the disclosed subject matter, which is only limited by the claims which follow. Features of the disclosed embodiments can be combined and rearranged in various ways. Without departing from the spirit and scope of the disclosed subject matter, modifications, equivalents, or improvements to the disclosed subject matter are understandable to those skilled in the art and are intended to be encompassed within the scope of the present disclosure.

1-20. (canceled)

21. A method for forming a polycrystalline silicon thin film, comprising:
providing an amorphous silicon thin film; and
performing a laser annealing process to convert the amorphous silicon thin film into a polycrystalline silicon thin film through generating a laser irradiation having a spatially periodic intensity distribution to irradiate the amorphous silicon thin film;
wherein the spatially periodic intensity distribution comprises:
a first laser intensity to form a plurality of crystal nuclei regions arranged in an array, and
a second laser intensity to form a plurality of epitaxial growth regions, the second laser intensity being greater than the first laser intensity.

22. The method of claim 21, wherein the laser annealing process further comprising:
a cooling process to form multiple crystal grains that grow from the crystal nuclei regions.

23. The method of claim 21, wherein the first laser intensity is less than a critical intensity value that is a minimum intensity of a laser irradiation to completely melt the amorphous silicon thin film.

24. The method of claim 23, further comprising:
using an optical film to control the spatially periodic intensity distribution of the laser irradiation, wherein:
the optical film comprises a plurality of optical plates that are arranged in an array, and
a laser beam going through each optical plate has a central symmetrical intensity distribution.

25. The method of claim 24, wherein:
the plurality of optical plates are arranged as a matrix; and
the spatially periodic intensity distribution of the laser irradiation is capable of converting an amorphous silicon thin film into a polycrystalline silicon thin film comprising rectangular crystal grains.

26. The method of claim 24, wherein:
the plurality of optical plates are arranged as a parallelogram array; and
the spatially periodic intensity distribution of the laser irradiation is capable of converting an amorphous silicon thin film into a polycrystalline silicon thin film comprising hexagonal crystal grains.

27. The method of claim 24, wherein:
the optical film comprises a plurality of weak light regions; and
a laser beam going through each weak light region has an intensity that is less than the critical intensity value.

28. The method of claim 21, further comprising:
providing a base substrate, wherein the amorphous silicon thin film is formed on the base substrate; and
forming a barrier layer between the base substrate and the amorphous silicon thin film.

29. The method of claim 28, wherein the crystal nuclei are located in one side of the polycrystalline silicon thin film that is close to the base substrate.

30. An optical film for forming a polycrystalline silicon thin film, comprising:
a plurality of optical plates arranged in an array for generating a spatially periodic intensity distribution of a laser irradiation through the optical film; and
a plurality of weak light regions for forming a plurality of crystal nuclei regions arranged in an array.

31. The optical film of claim 30, wherein each weak light region is used for controlling an intensity of laser going through the region to incompletely melt a corresponding region of an amorphous silicon thin film.

32. The optical film of claim 30, wherein:
the plurality of optical plates are arranged as a matrix; and
the spatially periodic intensity distribution of the laser irradiation is capable of converting an amorphous silicon thin film into a polycrystalline silicon thin film comprising rectangular crystal grains.

33. The optical film of claim 30, wherein:
the plurality of optical plates are arranged as a parallelogram array; and
the spatially periodic intensity distribution of the laser irradiation is capable of converting an amorphous silicon thin film into a polycrystalline silicon thin film comprising hexagonal crystal grains.

34. The optical film of claim 30, wherein each optical plate is a zone plate.

35. The optical film of claim 34, wherein each optical plate is a Fresnel zone plate.

36. The optical film of claim 30, wherein each optical plate is a convex lens.

37. The optical film of claim 30, wherein each optical plate has a quadrilateral shape.

38. The optical film of claim 37, wherein each optical plate is configured for quadrilaterally converging an incident light.

39. A polycrystalline silicon thin film, comprising a polycrystalline silicon thin film formed by the method according to claim 21.

40. A thin film transistor, comprising a polycrystalline silicon thin film according to claim 39.
